(19) United States
(12) Patent Application Publication
(10) Pub. No.: US 2010/0014945 A1
(43) Pub. Date: Jan. 21, 2010

(54) SEMICONDUCTOR PROCESSING APPARATUS HAVING ALL-ROUND TYPE WAFER HANDLING CHAMBER

(75) Inventors: Masahiro Takizawa, Nagaoka-shi (JP); Teruhide Nishino, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 12/174,491

(22) Filed: Jul. 16, 2008

(51) Int. Cl. H01L 21/677

(52) U.S. Cl. 414/217

(57) ABSTRACT

A semiconductor manufacturing apparatus includes a wafer handling chamber; at least one wafer input/output chamber attached to the wafer handling chamber; and multiple wafer processing chambers attached to the wafer handling chamber. The wafer handling chamber has a polygonal shape on a processing chamber level on which the wafer processing chambers are installed, and one wafer processing chamber is installed on each and every side of the polygon.

### BACKGROUND

1. Field of the Invention

The present invention generally relates to a semiconductor wafer handling chamber and a semiconductor manufacturing apparatus using the same.

2. Description of the Related Art

With semiconductor manufacturing apparatuses used in the production of semiconductors, the number of semiconductor wafers processed per unit time (i.e., throughput) has become an issue of great interest in recent years. One way to improve throughput is to increase the number of semiconductor wafer processing chambers attached to the semiconductor manufacturing apparatus in order to implement parallel processing, thereby increasing the number of semiconductor wafers processed.

However, attempts to increase the number of semiconductor wafer processing chambers by increasing the size of the wafer handling chamber and arranging multiple semiconductor wafer processing chambers two-dimensionally around the wafer handling chamber are limited by the area of the clean room used for semiconductor manufacturing. Also, merely stacking multiple semiconductor wafer processing chambers vertically reduces the maintainability of the apparatus.

A semiconductor manufacturing apparatus disclosed in Japanese Patent Laid-open No. 9-104982, for example, has multiple semiconductor wafer processing chambers that are installed on one wall of the semiconductor manufacturing apparatus with a space in the vertical direction provided between the adjacent chambers.

However, the apparatus of Japanese Patent Laid-open No. 9-104982 installs the semiconductor wafer processing chambers only on one side of the apparatus and since the number of semiconductor wafer processing chambers that can be installed on the one side is limited, increases in throughput are limited.

### SUMMARY

To solve one or more of the aforementioned problems, the semiconductor manufacturing apparatus proposed by an aspect of the present invention is characterized in that the semiconductor manufacturing apparatus comprises: (i) a wafer handling chamber, (ii) at least one wafer input/output chamber attached to the wafer handling chamber, and (iii) multiple wafer processing chambers attached to the wafer handling chamber, wherein the wafer handling chamber has a polygonal shape on a processing chamber level for installing the wafer processing chambers, and one wafer processing chamber is installed on each and every side of the polygon (i.e., all-round the wafer handling chamber). The wafer input/output chamber may be installed on an in-out chamber level disposed above or below the processing chamber level with respect to the axial direction of the wafer handling chamber.

In another embodiment, each and every side of a wafer handling chamber having a polygonal shape may have at least two wafer processing chambers in an axial direction of the wafer handling chamber, and a wafer input/output chamber is installed between the upper wafer processing chambers and the lower processing chambers with respect to the axial direction. There are at least two processing chamber levels for installing the wafer processing chambers, and the wafer input/output chamber is installed on an in-out chamber level arranged between the two processing chamber levels, i.e., between the upper processing chamber level and the lower processing chamber level. In an embodiment, the multiple wafer processing chambers installed on one side are apart from each another in the axial direction of the wafer handling chamber, which makes maintenance easy.

Based on the above configurations, a semiconductor manufacturing apparatus can be provided that implements parallel processing using an increased number of wafer processing chambers to improve the throughput, without reducing maintainability.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a schematic plane view of a conventional semiconductor wafer manufacturing apparatus using a hexagonal semiconductor wafer handling chamber and four semiconductor wafer processing chambers.

FIG. 2 is a schematic plane view of a semiconductor wafer manufacturing apparatus according to an embodiment of the present invention, where the height of the semiconductor wafer handling chamber is increased, relative to the wafer handling chamber of FIG. 1, and this hexagonal semiconductor wafer handling chamber is used together with six semiconductor wafer processing chambers to improve throughput.

FIG. 3 is a schematic side view of the semiconductor manufacturing apparatus shown in FIG. 2 according to an embodiment of the present invention.

FIG. 4 is a schematic side view of a semiconductor manufacturing apparatus according to an embodiment of the present invention, where the height of the semiconductor wafer handling chamber is increased, relative to the wafer handling chamber of FIG. 2, and this hexagonal semiconductor wafer handling chamber is used together with 12 semiconductor wafer processing chambers to improve throughput.

### DETAILED DESCRIPTION

The present invention will be explained in detail with reference to preferred embodiments which are not intended to limit the present invention.

According to embodiments of the invention, a semiconductor manufacturing apparatus is provided comprising: (i) a wafer handling chamber; (ii) at least one wafer input/output chamber attached to the wafer handling chamber; and (iii) multiple wafer processing chambers attached to the wafer handling chamber, wherein the wafer handling chamber has a polygonal shape on a processing chamber level for installing the wafer processing chambers, and one wafer processing chamber is installed on each and every side of the polygon. The wafer handling chamber is an all-round type wafer handling chamber where all of the sides of the polygon are provided with respective wafer processing chambers. By using the all-round type wafer handling chamber, the throughput can effectively be increased. In various embodiments, the number of sides of the polygon may be 3-10 (typically 4-8, preferably 4, 5, 6, or 7).

Embodiments of the invention include, but are not limited to, the following:

In an embodiment, the wafer input/output chamber is attached to the wafer handling chamber and may be disposed on an in-out chamber level above or below the processing chamber level. The in-out chamber level may be arranged above or below the processing chamber level in the axial direction of the wafer handling chamber. In an embodiment, the wafer handling chamber may comprise a vacuum handling robot for transferring a wafer at least between the wafer input/output chamber and one of the wafer processing chambers, and a robot movement actuator for moving the vacuum robot vertically and horizontally (or in the axial direction and directions perpendicular to the axial direction). When the wafer handling chamber has at least one processing level and one in-out chamber level arranged in the axial direction, the height of the wafer manufacturing apparatus increases as compared with a conventional apparatus. If the robot movement actuator is installed above the wafer handling chamber, the height of the wafer manufacturing apparatus increases more as measured from the floor level. However, this avoids lowering the level of the floor under the robot movement actuator to accommodate the robot movement actuator.

In an embodiment, on the processing chamber level, solely the wafer processing chambers are installed, and on the in-out chamber level, solely the wafer input/output chamber(s) is/are installed. The number of the wafer input/output chambers may typically be two, but can be one or more than two depending on the number of the wafer processing chambers, the overall size of the wafer manufacturing apparatus, etc.

In any of the foregoing embodiments, the at least one wafer input/output chamber may be composed of two wafer input/output chambers. In an embodiment, the two wafer input/output chambers may be installed on two adjacent sides of the polygon of the semiconductor wafer handling chamber.

In any of the foregoing embodiments, the wafer manufacturing apparatus may further comprise another processing chamber level above or below the processing chamber level defined as a first processing chamber level, said another processing chamber comprising a wafer handling chamber having a polygonal shape wherein one wafer processing chamber is installed on each and every side of the polygon. In an embodiment, the wafer input/output chamber may be attached to the wafer handling chamber on the in-out chamber level arranged between the first and second processing chamber levels. In that configuration, a distance between the first and second processing chamber levels can be kept wide (e.g., 700 mm to 1,000 mm) for improving the maintainability of the apparatus.

The number of the processing chamber levels can be more than two (e.g., three or four). A distance between two immediately adjacent processing chamber levels should preferably be kept wide for improving the maintainability of the apparatus.

In any of the foregoing embodiments, the first processing chamber level and the second processing chamber level may have substantially the same structures in the axial direction of the wafer handling chamber.

In any of the foregoing embodiments, the wafer manufacturing apparatus may further comprise a mini-environment including an atmospheric handling robot, which is attached to the wafer input/output chamber opposite the wafer handling chamber. In an embodiment, the wafer manufacturing apparatus may further comprise wafer storage chambers attached to the mini-environment opposite the wafer input/output chamber.

Embodiments of the present invention will be explained with reference to drawings which are not intended to limit the present invention.

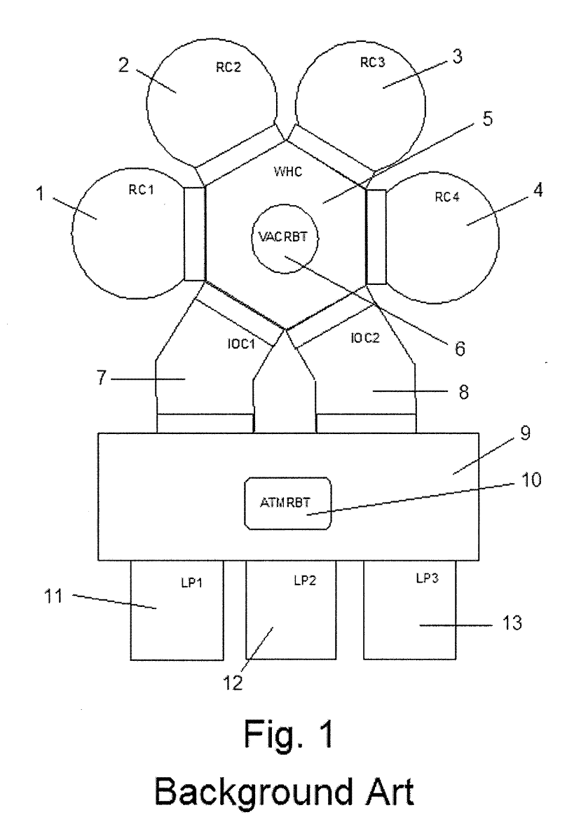

FIG. 1 is a schematic drawing showing an example of a conventional semiconductor manufacturing apparatus. This apparatus comprises separate chambers (modules) designated as follows:

IOC1, IOC2: Wafer input/output chamber, or in-out chamber, 7, 8

WHC: Wafer handling chamber 5

RC1, RC2, RC3, RC4: Wafer processing chamber 1, 2, 3,4

FIG. 1 also shows the following components:

LP1, LP2, LP3: Wafer storage chamber (FOUP) loading port or load port 11, 12, 13

ATMRBT: Atmospheric handling robot or atmospheric robot 10

Furthermore, the WHC houses the following component:

VACRBT: Vacuum handling robot or vacuum robot 6

The four processing chambers 1, 2, 3, 4 and the two in-out chambers 7, 8 are installed on the sides of the hexagonal wafer handling chamber 5. The in-out chambers 7, 8 are connected to one side of a mini-environment 9 wherein the atmospheric robot 10 is installed. To the other side opposite to the mini-environment 9, the load ports 11, 12, 13 are connected.

A semiconductor wafer is stored normally in a semiconductor wafer storage chamber called a “FOUP (Front Opening Unified Pod)” and placed in the load port 11, 12, or 13. Then, the semiconductor wafer is transferred in atmosphere by the atmospheric robot 10 to the in-out chamber 7 or 8, and then transferred in vacuum by the vacuum robot 6 from the in-out chamber 7 or 8 to one of the processing chambers 1, 2, 3, and 4 to undergo chemical processing inside the processing chamber. When the processing is completed, the semiconductor wafer returns from the processing chamber to the FOUP by following the same steps in reverse.

FIG. 1 shows four processing chambers 1, 2, 3, 4. If all of the processing chambers are assumed to apply the same chemical processing to a semiconductor wafer, simultaneous parallel processing using these four processing chambers increases the throughput of the semiconductor manufacturing apparatus (i.e., number of semiconductor wafers processed per unit time) substantially or nearly in proportion to the number of processing chambers (although strictly speaking the increase in throughput may not be exactly proportional to the number of processing chambers depending on the processing time in each semiconductor wafer processing chamber, time needed by the robot to transfer each semiconductor wafer, etc.). Accordingly, the higher the number of the processing chambers, the higher the productivity of the semiconductor manufacturing apparatus becomes. However, as can be understood from FIG. 1, the conventional semiconductor manufacturing apparatus does not have an extra space for installing any more processing chambers.

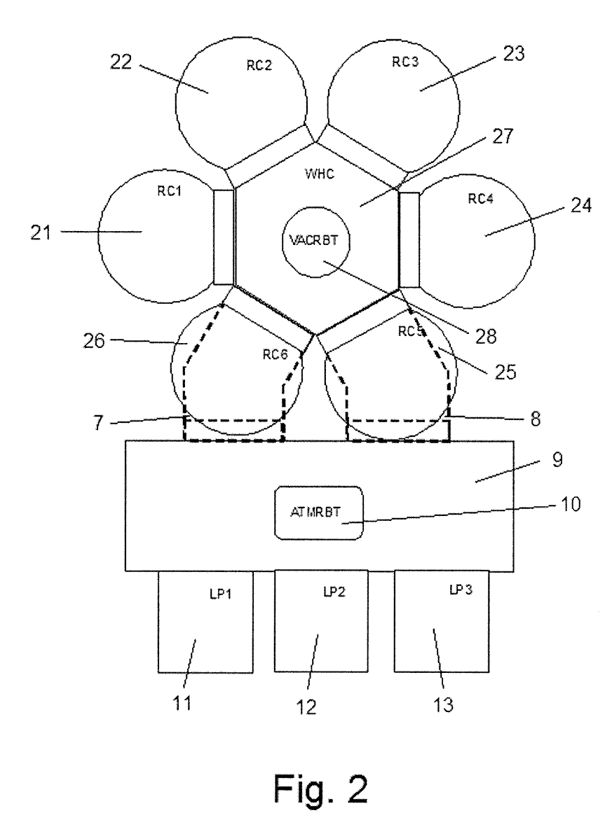

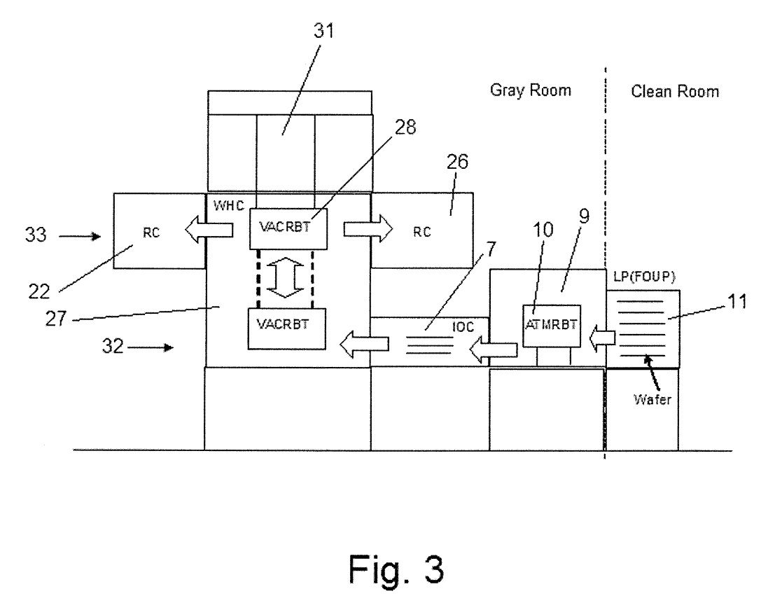

However, this unavailability of space occurs when movements of semiconductor wafers are limited to two dimensions. If semiconductor wafers can be moved three-dimensionally, then a semiconductor manufacturing apparatus like the one shown in FIG. 2 is feasible. In FIG. 2, the wafer input/output chambers are shown in dotted lines since they are hidden for the most part as viewed from above the wafer handling chamber. The number of processing chambers has increased from four to six. FIG. 3 gives a side view of the semiconductor manufacturing apparatus shown in FIG. 2.

In FIG. 3, the in-out chambers 7, 8 are installed below the processing chambers 21-26 (FIG. 2). That is, the in-out chambers 7, 8 are installed on the in-out chamber level 32, and the processing chambers 22-26 are installed on the processing chamber level 33, which is arranged above the in-out chamber level 32 in the axial direction of the wafer handling chamber in this illustrated embodiment. Here, the vacuum robot 28 moves vertically (in the Z direction) to transfer wafers from the in-out chambers 7, 8 to the processing chambers 21-26. The vacuum robot 28 is operated by a robot movement actuator 31. Normally the robot movement actuator 31 is installed below the wafer handling chamber. In the illustrated embodiment, however, the robot movement actuator 31 is installed above the wafer handling chamber 27 because a height corresponding to the length of the Z-axis stroke of the vacuum robot 28 (which is approximately equal to the height of the robot movement actuator 31) needs to be accommodated and it is preferable to avoid the passing of the robot movement actuator 31 under the floor (for this purpose, the height of the semiconductor wafer handling chamber is increased in FIG. 3). The wafer handling chamber 27, the processing chambers 21-26, the in-out chamber 7, and the mini-environment 9 are disposed in a gray room (air-controlled environment not as clean as a clean room), whereas the load port 11 is disposed in a clean room.

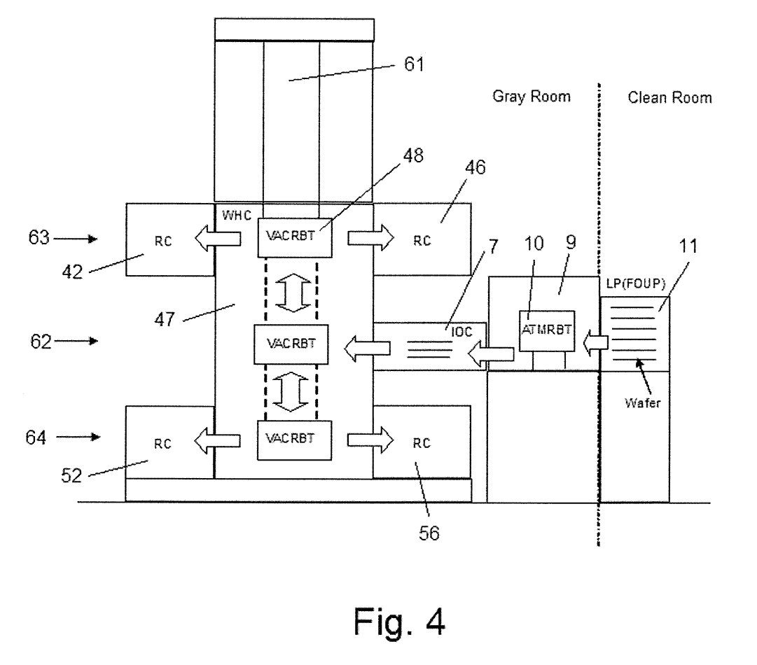

With reference to FIG. 4, the number of wafer processing chambers is further extended. A wafer handling chamber 47 has two processing chamber levels 63, 64, between which an in-out chamber level 62 is arranged. One processing chamber is installed on each and every side of the wafer handling chamber on both the processing chamber levels 63, 64. Since this is a side view, processing chambers 42, 46 on the upper processing chamber level 63, and processing chambers 52, 56 on the lower processing chamber level 64 are shown. However, the wafer handling chamber 47 has a hexagonal shape, and in reality there are 12 processing chambers (6 processing chambers per level×2 levels=12 processing chambers). Accordingly, this semiconductor manufacturing apparatus has three times the throughput of the apparatus shown in FIG. 1.

Further, the semiconductor manufacturing apparatus shown in FIG. 4 requires a longer Z-axis stroke (length) for the vacuum robot 48 compared to the apparatus shown in FIG. 3, and consequently the height of the semiconductor manufacturing apparatus becomes is further increased. That is, a robot movement actuator 61 has a length longer than that shown in the robot movement actuator 31.

Also as illustrated, there is a space between the processing chambers on the upper processing chamber level 63 and the processing chambers on the lower processing chamber level 64, thereby facilitating maintenance (this space is preferable because semiconductor wafer processing chambers are normally structured in such a way that the top part is opened to carry out maintenance).

In the above examples, apparatus having six processing chambers (FIGS. 2 and 3) or 12 processing chambers (FIG. 4) installed on a hexagonal wafer handling chamber have been explained. However, the shape of the wafer handling chamber is not at all limited to hexagon. It goes without saying that as long as the length of one side of the wafer handling chamber does not become smaller than the diameter of the semiconductor wafer, theoretically an N-gonal handling chamber with an N×2 number of processing chambers can be installed in FIG. 4, and an N number of processing chamber can be installed in FIG. 3.

Also, an example where one processing chamber is installed both on top and bottom of an in-out chamber has been illustrated (FIG. 4). Here, too, theoretically processing chambers can be installed on additional higher levels, to the extent permitted by the height of the semiconductor manufacturing apparatus.

Further, the N-gonal handling chamber has an N number of sides which may have equal length or may have different length as long as the wafer can pass therethrough. Also, the angles formed by two adjacent sides of the polygonal handling chamber may be same or may be different; for example, the angle formed between the sides to which the in-out chambers are attached may be greater than all other angles formed by the remaining sides.

Additionally, in an embodiment, a combination of a conventional wafer handling chamber and an all-round type wafer handling chamber according to any of the embodiments of the present invention can be utilized. For example, an N number of processing chambers and two in-out chambers are installed on a lower level of a wafer handling chamber, and an N+2 number of processing chambers are installed on an upper level of the wafer handling chamber. Additionally, another lower level can be provided with an N+2 number of processing chambers under the lower level. In these embodiments, a single in-out chamber can be used instead of the two in-out chambers.

Further, the in-out chamber level and the processing chamber level need not have the same number of sides and can independently have its own polygonal shape. Likewise, in the case of multiple processing chamber levels, the processing chamber levels can have different polygonal shapes. A gate valve is typically provided between the processing chamber and the wafer handling chamber, between the wafer handling chamber and the in-out chamber, and between the in-out chamber and the mini-environment. In an embodiment, boundaries between the wafer handling chamber and the gate valves define the polygonal shape of the wafer handling chamber on a plane perpendicular to the axial direction of the wafer handling chamber.

The processing chambers may perform the same processing operation or may perform different processing operations. The processing chamber may be a plasma CVD reactor, a thermal CVD reactor, an ALD reactor, an annealing chamber, an etching chamber, etc. Further, the processing chamber may comprise a transferring chamber and a reaction chamber disposed on top of the transferring chamber.

In the present disclosure where conditions and/or structures are not specified, the skilled artisan in the art can readily provide such conditions and/or structures, in view of the present disclosure, as a matter of routine experimentation.

From the above, a semiconductor manufacturing apparatus conforming to embodiments of the present invention uses an all-round type wafer handling chamber, and further at least two processing chambers are installed on each side of a polygonal semiconductor wafer handling chamber, thereby improving the throughput, without reducing the maintainability, by parallel processing using an increased number of semiconductor wafer processing chambers.

The present invention includes the above mentioned embodiments and other various embodiments including the following:

1) A semiconductor manufacturing apparatus comprising semiconductor wafer input/output chambers, a semiconductor wafer handling chamber, and semiconductor wafer processing chambers, said semiconductor manufacturing apparatus characterized in that the semiconductor wafer handling chamber has an N-gonal shape and at least two semiconductor wafer processing chambers are installed on each side of the N-gon.

2) A semiconductor manufacturing apparatus according to 1), characterized in that two semiconductor wafer processing chambers are installed on each side of the N-gon of the semiconductor wafer handling chamber.

3) A semiconductor manufacturing apparatus according to 1), characterized in that the semiconductor wafer input/output chambers are installed on two adjacent sides of the N-gon of the semiconductor wafer handling chamber.

4) A semiconductor manufacturing apparatus according to 2), characterized in that each of the semiconductor wafer input/output chambers is installed between the two semiconductor wafer processing chambers installed on one side of the N-gon of the semiconductor wafer handling chamber.

5) A semiconductor manufacturing apparatus comprising semiconductor wafer input/output chambers, a semiconductor wafer handling chamber, and semiconductor wafer processing chambers, said semiconductor manufacturing apparatus characterized in that the semiconductor wafer handling chamber has an N-gonal shape and one semiconductor wafer processing chamber is installed on each side of the N-gon.

6) A semiconductor manufacturing apparatus according to 5), characterized in that the semiconductor wafer input/output chambers are installed below the semiconductor wafer processing chambers.

It will be understood by those of skill in the art that numerous and various modifications can be made without departing from the spirit of the present invention. Therefore, it should be clearly understood that the forms of the present invention discussed herein are illustrative only and are not intended to limit the scope of the present invention.

What is claimed is:

1. A semiconductor manufacturing apparatus, comprising:
a wafer handling chamber;
at least one wafer input/output chamber attached to the wafer handling chamber; and
multiple wafer processing chambers attached to the wafer handling chamber,
wherein the wafer handling chamber has a polygonal shape on a processing chamber level for installing the wafer processing chambers, and one wafer processing chamber is installed on each and every side of the polygon on the processing chamber level.

2. The semiconductor manufacturing apparatus according to claim 1, wherein the wafer input/output chamber is attached to the wafer handling chamber on an in-out chamber level above or below the processing chamber level.

3. The semiconductor manufacturing apparatus according to claim 2, wherein the wafer handling chamber comprises a vacuum handling robot for transferring a wafer at least between the wafer input/output chamber and one of the wafer processing chambers, and a robot movement actuator for moving the vacuum robot vertically and horizontally.

4. The semiconductor manufacturing apparatus according to claim 3, wherein the robot movement actuator is disposed above the wafer handling chamber.

5. The semiconductor manufacturing apparatus according to claim 1, wherein the at least one wafer input/output chamber is composed of two wafer input/output chambers.

6. The semiconductor manufacturing apparatus according to claim 5, wherein the two wafer input/output chambers are installed on two adjacent sides of the polygon of the semiconductor wafer handling chamber on an in-out chamber level above or below the processing chamber level.

7. The semiconductor manufacturing apparatus according to claim 1, further comprising a second processing chamber level above or below the processing chamber level defined as a first processing chamber level, said second processing chamber level comprising a wafer handling chamber having a polygonal shape wherein one wafer processing chamber is installed on each and every side of the polygon on the second processing chamber level.

8. The semiconductor manufacturing apparatus according to claim 7, wherein the processing chambers on the first processing chamber level and the processing chambers on the second processing chamber level are effectively distanced to perform a maintenance operation of each processing chamber.

9. The semiconductor manufacturing apparatus according to claim 7, wherein the wafer input/output chamber is attached to the wafer handling chamber on an in-out chamber level between the first and second processing chamber levels.

10. The semiconductor manufacturing apparatus according to claim 7, wherein the first processing chamber level and the second processing chamber level have substantially the same structures in the axial direction of the wafer handling chamber.

11. A semiconductor manufacturing apparatus, comprising:
multiple wafer processing chambers;
at least one wafer input/output chamber; and
a wafer handling chamber having at least one processing chamber level and an in-out chamber level arranged in the axial direction of the wafer handling chamber,
wherein the wafer handling chamber has a polygonal shape on each processing chamber level, and one wafer processing chamber is installed on each and every side of the polygon on the processing chamber level,
wherein the wafer input/output chamber is installed on the in-out chamber level.

12. The semiconductor manufacturing apparatus according to claim 11, wherein the wafer handling chamber comprises a vacuum handling robot for transferring a wafer at least between the wafer input/output chamber and one of the wafer processing chambers, and a robot movement actuator for moving the vacuum robot vertically and horizontally.

13. The semiconductor manufacturing apparatus according to claim 12, wherein the robot movement actuator is disposed above the wafer handling chamber.

14. The semiconductor manufacturing apparatus according to claim 11, wherein the at least one wafer input/output chamber is composed of two wafer input/output chambers.

15. The semiconductor manufacturing apparatus according to claim 14, wherein the two wafer input/output chambers are installed on two adjacent sides of the polygon of the semiconductor wafer handling chamber on the in-out chamber level.

16. The semiconductor manufacturing apparatus according to claim 11, wherein the at least one processing chamber level is composed of two or more processing chamber levels.

17. The semiconductor manufacturing apparatus according to claim 16, wherein two or more processing chamber levels consists of two processing chamber levels.

18. The semiconductor manufacturing apparatus according to claim 17, wherein the in-out chamber level is arranged between the two processing chamber levels.

19. The semiconductor manufacturing apparatus according to claim 11, further comprising a mini-environment including an atmospheric handling robot, which is attached to the wafer input/output chamber opposite the wafer handling chamber.

20. The semiconductor manufacturing apparatus according to claim 18, further comprising wafer storage chambers attached to the mini-environment opposite the wafer input/output chamber.
